(19) United States
(12) Patent Application Publication
(10) Pub. No.: US 2026/0264418 A1
(43) Pub. Date: Sep. 10, 2026

(54) DUAL SUBSTRATE PROCESSING

(71) Applicant: Kateeva, Inc., Newark, CA (US)

(72) Inventor: Alexander Sou-Kang Ko, Santa Clara, CA (US)

(73) Assignee: Kateeva, Inc., Newark, CA (US)

(21) Appl. No.: 18/849,302

(22) PCT Filed: Mar. 15, 2023
(86) PCT No.: PCT/US2023/064446

§ 371 Date: Sep. 20, 2024

Related U.S. Application Data
(60) Provisional application No. 63/362,283, filed on Mar. 31, 2022.
(60) Provisional application No. 63/365,017, filed on May 19, 2022.

(51) Int. Cl. B41J 3/62; B41J 3/407; B41J 3/54; B41J 11/00; B41J 13/10

(52) U.S. Cl. CPC B41J 3/62; B41J 3/407; B41J 3/543; B41J 11/00214; B41J 13/10

(57) ABSTRACT

Dual-substrate inkjet printers, radiation processing apparatus, and systems using such apparatus, are described herein. The dual-substrate inkjet printers have a substrate support, a print support extending across the substrate support and supporting a printhead assembly, a first substrate holder on a first side of the substrate support, and a second substrate holder on a second side of the substrate support opposite from the first substrate holder. The radiation processing apparatus includes a radiation source positioned to emit radiation to a treatment zone, a substrate support assembly comprising a substrate support surface having a long axis and a short axis, a plurality of manipulators located along a side of the substrate support assembly to engage at least two substrates, and a motion system to move the plurality of manipulators in a linear direction parallel to the long axis to move substrates into and out of the treatment zone.

### CROSS-REFERENCE TO RELATED MATTERS

This patent application claims benefit of U.S. Provisional Patent Application Ser. Nos. 63/365,017, filed May 19, 2022, and of 63/362,283, filed Mar. 31, 2022, each of which is entirely incorporated herein by reference.

### BACKGROUND

Industrial inkjet printers are used to apply materials to large substrates to form devices of all kinds. The substrates can be rigid or flexible, thick or thin, and can be made of an array of materials. The most common types of substrates used in this way are substrates made of various types of glass, which are processed to make electronic displays such as televisions and displays for smart phones.

In many applications, a material is deposited on a substrate using an inkjet printer or other deposition device. Typically, one substrate is processed at a time in one printer. The material can be a curable material that hardens when exposed to radiation. In such cases, the substrate is normally processed in an exposure chamber or tool. Typically, one substrate is also processed at a time in one exposure tool. Printing involves moving the substrate and/or a printhead to print material at desired locations on the substrate. The substrate is then usually moved to the exposure tool, where exposure processing may include preparation activities, at least activities such as substrate positioning and potentially thermal preparation and preparation of the deposited material for radiation processing. Production would be faster if two or more substrates could be prepared and/or processed concurrently.

### SUMMARY

Embodiments described herein provide an inkjet printer, comprising a substrate support; a print support extending across the substrate support and supporting a printhead assembly for dispensing material onto a substrate supported on the substrate support; a first substrate holder on a first side of the substrate support adjacent to a first substrate location on the substrate support to move a first substrate along the substrate support; and a second substrate holder on a second side of the substrate support opposite from the first substrate holder and adjacent to a second substrate location on the substrate support to move a second substrate along the substrate support.

Other embodiments described herein provide an inkjet printer, comprising a substrate support having a gas floatation system to provide a gas cushion, the substrate support comprising a processing zone having suction openings to control a pressure of the gas cushion in the processing zone, the suction openings being arranged in two groups that define a central gap in the processing zone; a print support extending across the substrate support at the processing zone and supporting a printhead assembly for dispensing material onto a substrate supported on the substrate support in the processing zone; a first substrate holder on a first side of the substrate support adjacent to a first substrate location on the substrate support to move a first substrate along the substrate support; and a second substrate holder on a second side of the substrate support opposite from the first substrate holder and adjacent to a second substrate location on the substrate support to move a second substrate along the substrate support.

Other embodiments described herein provide a processing system, comprising a processing section, comprising a dual-substrate inkjet printing chamber; a dual-substrate processing chamber; and a dual-substrate transfer chamber coupling the dual-substrate inkjet printing chamber and the dual-substrate processing chamber; and a dual-substrate interface chamber coupled to the processing section to provide two substrates in side-by-side arrangement for processing in the processing section.

Embodiments described herein provide a radiation source positioned to emit radiation to a treatment zone; a substrate support assembly comprising a substrate support surface having a long axis and a short axis; a plurality of manipulators located along a side of the substrate support assembly to engage at least two substrates; and a motion system to move the plurality of manipulators in a linear direction parallel to the long axis to move substrates into and out of the treatment zone.

Other embodiments described herein provide a radiation processing apparatus, comprising an enclosure with a window; a radiation source positioned outside the enclosure to emit radiation through the window to a treatment zone within the enclosure; a substrate support assembly comprising a substrate support surface having a long axis and a short axis, the substrate support surface having at least two processing sections, wherein the treatment zone is located between the two processing sections; a plurality of manipulators located along a side of the substrate support assembly to engage at least two substrates; and a motion system to move the plurality of manipulators in a linear direction parallel to the long axis to move substrates into and out of the treatment zone.

Other embodiments described herein provide a fabrication system, comprising a deposition apparatus to deposit a radiation-curable material on a substrate; a radiation processing apparatus to expose the radiation-curable material to radiation, the radiation processing apparatus comprising a radiation source positioned to emit radiation to a treatment zone; a substrate support assembly comprising a substrate support surface having a long axis and a short axis and a gas cushion support; a plurality of manipulators located along a side of the substrate support assembly to engage at least two substrates; and a motion system to move the plurality of manipulators in a linear direction parallel to the long axis to move substrates into and out of the treatment zone; and a transfer tool to move substrates between the deposition apparatus and the radiation processing apparatus.

### BRIEF DESCRIPTION OF THE DRAWINGS

FIG. 1 is a schematic plan view of a dual-substrate inkjet printer according to one embodiment.

FIG. 2 is a schematic plan view of a dual-substrate inkjet printer according to another embodiment.

FIG. 3A is a schematic plan view of a dual-substrate inkjet printer according to another embodiment.

FIG. 4 is a schematic plan view of a processing system according to one embodiment.

FIG. 5 is a plan view of a processing system according to another embodiment.

FIG. 6A is a plan view of a radiation processing apparatus according to one embodiment.

FIG. 6B is an elevation view of a portion of the apparatus of FIG. 6A.

FIG. 6C is a plan view of a processing system according to another embodiment.

FIG. 7 is a plan view of a radiation processing apparatus according to another embodiment.

FIG. 8 is a plan view of a radiation processing apparatus according to another embodiment

FIG. 9 is a plan view of a radiation processing apparatus according to another embodiment.

FIG. 10 is a plan view of a fabrication system according to one embodiment.

FIG. 11 is a plan view of a fabrication system according to another embodiment.

FIG. 12 is a plan view of a fabrication system according to another embodiment.

FIG. 13 is a plan view of a fabrication system according to another embodiment.

### DETAILED DESCRIPTION

Methods and apparatus for dual-substrate processing in an industrial inkjet printing process are described herein. The apparatus described herein enable two substrates to be printed in a single apparatus simultaneously, concurrently, partially concurrently, partially sequentially, or sequentially. The apparatus described herein also enable two substrates to be irradiated in a single apparatus simultaneously, concurrently, partially concurrently, partially sequentially, or sequentially. These tools provide capability to stage, print, and irradiate multiple substrates in a semi-continuous manner with small overall dual-substrate processing apparatus footprint.*** The radiation processing tools herein generally have substrate input and output, which can be at the same location or in different locations, and at least two processing sections, with a plurality of manipulators to manipulate at least two substrates. These tools generally have a linear layout, where substrates move linearly within the tools, in only one linear direction or in multiple linear directions. The tools can have one or more radiation sources, each of which can be stationary or movable. Substrates can be stationary or in motion during exposure. The tool can be housed in an enclosure, with the radiation source inside the enclosure or outside the enclosure with a window to transmit radiation into the enclosure.

Inkjet printers and printing systems are described herein that can process dual-substrates. The printers herein can perform inkjet printing on two substrates concurrently, and the printing systems can process two substrates concurrently using the dual-substrate printers described herein along with other dual-substrate modules. One printing system described herein can accept single substrates, pair substrates for dual processing, and return single substrates after processing. Another printing system described herein can accept dual-substrates and return dual-substrates.

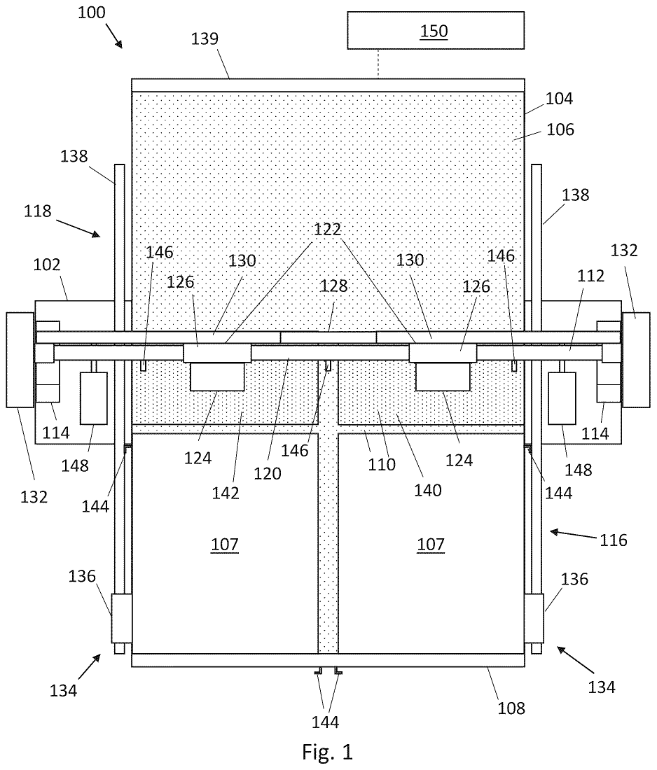

FIG. 1 is a schematic plan view of an inkjet printer 100 according to one embodiment. The inkjet printer 100 is a dual-substrate printer. The inkjet printer 100 has a base 102 made of a dense, strong material such as granite. A substrate support 104 is supported on the base. The substrate support 104 may rest directly on the base 102, or the substrate support 104 can be supported on the base 102 by support members (not shown), which can be strong resilient members, such as rubber pads, or can be gas cushion supports.

The substrate support 104 is a gas cushion support, with openings 106 to provide a flow of gas to create a gas cushion that supports a substrate 107 above the surface of the substrate support 104. Here, two substrates 107 are disposed on the substrate support 104 for processing by the inkjet printer 100. The substrate support 104 has a first staging area 108 where the substrates 107 are placed to begin processing. The first staging area 108 has a plurality of openings 110 for flowing gas to the substrate support 104 to form a gas cushion on which to float the two substrates 107. Here, the openings 110 are distributed uniformly across the first staging area 108, including at locations where no substrate surface covers the first staging area 108. Where a maximum size of the substrates to be processed on the printer 100 is known, openings 110 can be omitted from areas of the substrate support 104 that would not support any part of a substrate. In this case, for example, the openings 110 could be omitted along the central longitudinal strip between the two substrates 107.

A print support 112 is also supported on the base 102. The print support 112 includes two stands 114, each stand 114 resting on the base 102 on opposite sides of the substrate support 104. Thus, a first stand 114 rests on the base 102 at a first side 116 of the substrate support 104 and a second stand 114 rests on the base 102 at a second side 118 of the substrate support 104, opposite from the first side 116. A printhead support 120 rests on the two stands 114 and extends across the substrate support 104 from the first side 116 to the second side 118. The stands 114 and the printhead support 120 are typically made of a structurally strong material, which can be a dense material like the material of the base 102.

Two printhead assemblies 122 are coupled to the printhead support 120. The printhead assemblies 122 are movably coupled to the printhead support 120 to move along the printhead support 120 in a lateral direction. Each printhead assembly 122 has a printhead unit 124 coupled to a carriage 126. The carriage 126 is coupled to the printhead support 120 to provide movement of the printhead assembly 122 along the printhead support 120. Each carriage 126 includes a linear actuator (not shown) to accomplish movement of the printhead assembly 122. The carriage 126 can have an air bearing support to provide substantially frictionless movement of the printhead assembly 122 along the printhead support 120. Each printhead 124 can be coupled to the respective carriage 126 by a lifter that can position the printhead 124 at a desired elevation with respect to the substrate support 104.

A utility tray 128 is coupled to the printhead support 120 along a side thereof. The utility tray 128 is positioned to avoid interrupting movement of the carriages 126 along the printhead support 120. The utility tray 128 supports various wires, cables, conduits, and other utility members that provide materials and/or power to the printhead assemblies 122. Here, each printhead assembly 122 is coupled to a utility bundle 130 that is supported by the utility tray 128. Each utility bundle 130 couples a respective printhead assembly 122 to a supply unit 132. There are two supply units 132, a first supply unit 132 located at the first side 116 of the substrate support 104 and a second supply unit 132 located at the second side 118 of the substrate support 104. The supply units 132 are not supported by the base 102 here, but one or more of the supply units 132 could be supported by the base 102. The supply units 132 manage supply of materials to the printhead assemblies 122. Instead of two supply units 132, one for each printhead unit 124, a single supply unit 132 could be used, with appropriate piping and valving, to supply materials to both printhead units 124.

Along each side of the substrate support 104 is a substrate holder 134. A first substrate holder 134 is disposed along the first side 116 of the substrate support 104 and a second substrate holder 134 is disposed along the second side 118 of the substrate support 104. Each substrate holder 134 has a contact member 136 coupled to a holder support 138 that extends along the side of the substrate support 104 in the longitudinal direction of the substrate support 104. The contact member 136 of each substrate holder 134 is movably supported by a respective holder support 138 so the contact member 136 can move along the holder support 138 beside the substrate support 104. The contact member 136 of each substrate holder 134 is configured to engage with one of the substrates 107 at an edge thereof to move and position the substrate 107 for processing. Each contact member 136 has a contact surface (not shown) that extends under the respective substrate 107 and engages with the substrate 107 using vacuum. When securely attached to the substrate 107, the contact member 136 can move along the holder support 134 to position the substrate 107 with respect to a printhead assembly 122 for processing.

The substrate support 104 has a second staging area 139 at the opposite end of the substrate support 104 from the first staging area 108. Like the first staging area 108, the second staging area 139 has a plurality of openings 110 for providing gas to form a gas cushion. As with the first staging area 108, openings 110 can be omitted in areas of the second staging area 139 that would not support a substrate, such as the central longitudinal strip.

Between the first and second staging areas 108 and 139, the substrate support 104 has a processing area 140 in a central region of the substrate support 104. The processing area 140, in this case, extends from the first side 116 to the second side 118 of the substrate support 104, but the processing area 140 could have a width that is less than the width, from the first side 108 to the second side 118, of the substrate support 104. The processing area 140 has a plurality of openings 110 for providing gas to form a gas cushion to support the substrates 107. The processing area 140 also has a plurality of gas removal openings 142 for removing gas of the gas cushion. Flowing gas to the openings 110 and removing gas through the gas removal openings 142 provides control over the pressure of the gas cushion, and therefore over the height the substrate floats above the substrate support 104 in the processing area 140.

The substrates 107 are generally moved together to avoid or minimize inertia and momentum moments that would reduce the accuracy of printing or would need to be dampened or settled before printing can begin. Thus, the substrates 107 are moved from the first staging area 108 to the processing area 140 together by operation of the substrate holders 134. While the substrates 107 are positioned with a portion of each substrate 107 at the processing area 140 of the substrate support 104, a gap between the substrates exposes a portion of the substrate support 104 during processing. During processing, microscopic droplets of print material are ejected from print nozzles of the two printhead units 124 toward the respective substrates 107. While processing, suction is applied to the gas removal openings 142, and any gas removal openings 142 not covered by a substrate would create a gas flow from above one or both substrates 107 into the exposed gas removal openings 142. Such gas flows can disrupt the trajectory of print material ejected from the nozzles of the printhead units 124 toward the substrates 107, diminishing print accuracy. Additionally, print material drawn into the gas removal openings can foul the openings, disrupting the gas cushion apparatus and potentially disrupting control of the gas cushion during processing. To avoid such circumstances, the gas removal openings are omitted in portions of the processing area 140 exposed and not covered by any substrate. The gas flow openings 110 can also be omitted in the exposed area, but allowing gas to flow through gas flow openings 110 in the gap between the substrates 107 can aid in thermal control of the substrate support 104 and of the substrates 107.

It should be noted that the gas removal openings 142 can, in some cases, be used not as gas removal openings, but as gas flow openings to provide gas flow to the gas cushion, such that all openings in the surface of the substrate support 104 are positive pressure gas flow openings.

The substrates 107 are generally positioned on the first staging area 108 of the substrate support 104 by a substrate handler (not shown) simultaneously, concurrently, sequentially, or partially sequentially. The substrate handler generally positions the substrate over the first staging area 108 and lowers the substrates 107 until the substrates 107 float off the substrate handler. The substrate handler then withdraws leaving the substrates 107 floating on the gas cushion of the first staging area 108. The substrates 107 are positioned for engagement with the substrate holders 134 by a positioning mechanism. In this case, the positioning mechanism includes a plurality of bankers 144, two bankers 144 for each substrate 107. The bankers 144 are located at the end of the first staging area 108 of the substrate support 104 and along the sides of the substrate support 104. The bankers 144 are actuated here to extend when positioning the substrates 107 and then to retract after the substrates 107 are engaged with the substrate holders 134. The bankers 144 generally retract away from and below the substrate support 104 to avoid interrupting movement of the substrate holders 134 along the sides of the substrate support 104. The bankers 144, in this case, are located near where the corners of the substrates 107 would be when the substrates 107 are placed on the first staging area 108. The bankers 144 are shaped, in this case, like corner features to capture the corners of the substrates 107, but in other cases the bankers 144 could have two curved or flat bumper contacts for each corner.

The two sets of bankers 144 are distributed in a left area and a right area of the first staging area 108. Thus, two bankers 144 are located at the end of the substrate support 104 adjacent to the first staging area 108 near the central longitudinal axis of the substrate support 104 and one banker 144 is located along each side 116, 118, of the substrate support 104 near the processing area 140. When a pair of substrates 107 is to be placed at the first staging area 108, the bankers are extended above the surface of the substrate support 104 and moved slightly away from the substrate placement area of the first staging area 108 to provide clearance for the substrate handler to place the substrates 107. When the substrate handler approaches and lowers the substrates 107 to the gas cushion, the bankers 144 are moved toward the substrates 107 to capture the substrates 107 and substantially immobilize the substrates 107. The substrate holders 134 are then moved to a home position, substantially as shown in FIG. 1, and vacuum is activated to engage the contact members 136 with the substrates 107. After the contact members 136 engage with the substrates 107 to hold the substrates 107 securely, the bankers 144 are moved away from the substrates 107 and retracted to an inactive position. At that time, the substrates are in position for measurement and print planning.

Imaging devices 146 are movably coupled to the printhead support 120. The imaging devices are generally used to image features on the substrates 107 to calibrate a print plan to the substrates 107 where they are actually placed on the substrate support 104. Because features to be printed on such substrates can be a few microns in size, slight inaccuracies in substrate placement or orientation, or of features previously created on the substrates, can affect printing accuracy. The imaging devices 146 are generally coupled to the printhead support 120 by a bearing system, for example a rail, or rails, mounted on a bottom side of the printhead support 120, and actuated by linear actuators to move along the printhead support 120 to desired locations. The imaging devices 146 are deployed in locations to enable imaging all areas of a substrate 107 while also facilitating movement of the printhead assemblies 122 as necessary to process the substrates. Thus, in this case, one imaging device 146 is located at each end of the printhead support 120 and one imaging device 146 is located between the two printhead assemblies 122. The imaging devices 146 generally move during print planning to image features on the substrates 107. Exact substrate position and orientation is ascertained using images of substrate features, and a print plan for each substrate is adjusted, as necessary, to correct for any substrate position, rotation, or distortion errors resolved from the imaged features. Following imaging, the imaging devices 146 located adjacent to one of the stands 114 can be moved to a position as close as possible to the closest stand 114 to avoid interrupting other processing. Imaging devices 146 between the two printhead assemblies 122 can be moved during processing to provide uninterrupted access for the printhead assemblies 122.

The printhead assemblies 122 are generally moved in the same direction at the same time to avoid generating unwanted vibration of components of the inkjet printer 100. A controller 150 is operatively coupled to all adjustable components of the inkjet printer 100 to control all operations including substrate intake and engagement, substrate positioning, imaging and print planning, printhead assembly positioning, gas support, and print material deposition. The controller 150 is configured to track position of at least the substrates 107 (using position indicators coupled to the contact members 136, not shown), the printhead assemblies 122, and the imaging devices 146, and is further configured to move any imaging devices 146 either occupying a location to which a printhead assembly 122, or occupying a position between the current location of a printhead assembly 122 and a location to which the printhead assembly 122 needs to be moved. Thus, if the printhead assemblies 122 need to be moved in the +x direction, and an imaging device 146 is currently at a location that would interfere with movement of one or more of the printhead assemblies 122, the imaging device 146 can be moved in the +x direction along with the printhead assemblies 122, and likewise if the printhead assemblies 122 need to be moved in the −x direction.

A printhead management station 148 is provided for each printhead assembly 122. Each printhead management station 148 may be supported on the base 102, as shown here, or may be supported from any support structures that may, for example, couple the substrate support 104 to the base 102. Each printhead management station 148 is located between a stand 114 and the corresponding holder support 138 so the nearest printhead assembly 122 can move to a position near the stand 114 to engage with the printhead management station 148. Each printhead management station 148 includes tools for managing a printhead and/or printhead assembly. The tools may include cleaning tools, calibration tools, diagnostic tools, and maintenance tools. Each printhead management station 148 may be actuated along a linear track in a direction perpendicular, or at least transverse, to a direction of motion of the printhead assemblies 122 to provide positional engagement of all the tools of the printhead management station 148 with the printhead 124.

As noted above, the printhead assemblies 122 are generally moved in the same direction at the same time. Likewise, the substrates 107 are generally moved in the same direction at the same time to minimize the effects of unbalanced inertial reactions on the stability of the inkjet printer 100. The substrates 107 are processed here in portrait orientation to minimize rotational inertial moments arising from movement of the substrates 107.

Print material is generally provided to each printhead assembly 122 in a quantity sufficient to perform a print job notwithstanding operation of the other printhead assembly 122. Here, each printhead assembly 122 has a dedicated supply unit 132 to supply print material, gases, other fluids, and power to the printhead assembly 122. Each printhead assembly 122 has local print material supply components that are provisioned from supply components in the supply unit 132, which may also have operator resupply facilities such as bulk loading stations.

In operation, two substrates 107 are disposed at the first staging area 108. Before the substrate are disengaged from the substrate handlers, the bankers 144 are deployed to limit substrate drift after the substrate handlers are withdrawn. The substrate handlers then disengage from the substrates 107, allowing the substrate 107 to engage with the substrate support 104, for example by floating on the gas cushion. The substrate handlers withdraw, and the bankers 144 are moved into contact with the substrates 107. The contact members 136 then move to a home position, if necessary, and engage with the substrates 107 at the edges thereof. The substrates 107 are then ready to be moved along the substrate support 104 for processing.

The substrates 107 are scanned for imaging by the imaging devices 146. Features are detected on each substrate 107, and any positioning, alignment, or distortion errors are detected. The print plan for each substrate is adjusted accordingly and printer control data is generated to execute the print plan. If necessary, the printhead assemblies 122 are engaged with the printhead management stations 148 to prepare and/or calibrate the inkjet printer 100 to process the substrates 107. The substrates 107 are then moved to provide printing access for the printhead assemblies 122. The printhead assemblies 122 are also moved, in concert with the substrates 107, to execute the print plan. The substrates 107 may be moved in only one direction during execution, or the substrates 107 may be moved back and forth, but the substrates 107, as much as possible, are only moved in the same direction at the same time. The printhead assemblies 122 are moved back and forth, as much as possible in the same direction at the same time. Any imaging devices 146 potentially interfering with movement of the printhead assemblies 122 are also moved.

After execution of the print plan, the substrates 107 are moved to one of the first and the second staging areas 108 and 139 to be retrieved by substrate handlers. The substrate handlers enter between the substrates 107 and the substrate support 104. The substrate handlers move upward to engage the substrate 107 and lift the substrates 107 off the gas cushion. As the substrate handlers engage with the substrate 107, the contact members 136 release the substrate 107 to the custody of the substrate handlers, which then withdraw carrying the substrates 107.

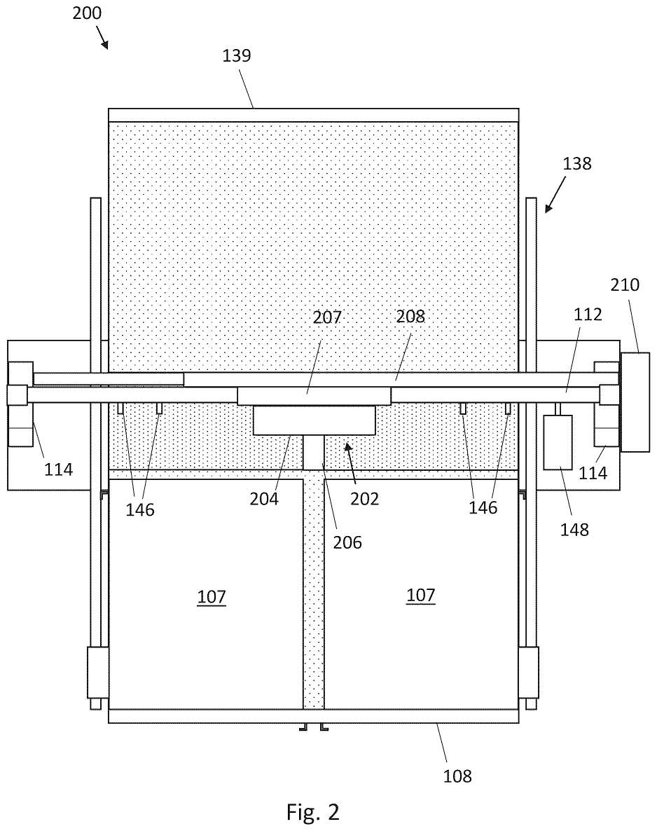

FIG. 2 is a schematic plan view of a dual-substrate inkjet printer 200 according to another embodiment. In this version, there is only one printhead assembly to deposit print material on two substrates. The inkjet printer 200 has one printhead assembly 202 coupled to the print support 112. The printhead assembly 202 has a printhead 204 that is larger than either of the printheads 124 to provide capacity for depositing print material on two substrates in a reasonable amount of time. The printhead assembly 202 includes a carriage 207, appropriately sized for the larger printhead 204, which couples the printhead 204 to the print support 112. The carriage 207 may be any type of suitable carriage, for example a gas bearing carriage. Here, there is only one utility bundle 208 and one supply unit 210, all appropriately scaled for the larger size of the printhead assembly 202. The utility bundle 208 is sized to provide reach for the printhead assembly 202 across the entire print support 112 from one stand 114 to the opposite stand 114. There is also only one printhead management station 148, located as in FIG. 1 between a stand 114 and the nearest holder support 138, although a redundant printhead management station 148 could be located between each stand 114 and the nearby holder support 138 on each side of the substrate support.

The imaging devices 146 are coupled to the print support 112, as described above in connection with FIG. 1, and are distributed here to either side of the printhead assembly 202. In this case, there are two imaging devices 146 on each side of the printhead assembly 202. Any number of imaging devices 146 can be used, and the imaging devices 146 can be configured to couple to the print support 112 in any suitable manner. For example, while here the imaging devices 146 are disposed on supports that extend laterally away from the print support 112 toward the first staging area 108, some imaging devices 146 could be disposed on supports that extend laterally away from the print support 112 toward the second staging area 139. For such imaging devices 146, the print support 112 would effectively be between the imaging devices 146 and the printhead 204. Combinations of such imaging devices can also be used.

The inkjet printer 200 can provide advantages over the inkjet printer 100. With only one printhead assembly, there are fewer moving parts to generate particles that can contaminate substrates. The single printhead assembly also needs only one printhead management station, although a redundant printhead management station could be provided in some cases for operational continuity. The single printhead assembly is larger in the inkjet printer 200 than either printhead assembly of the inkjet printer 100, requiring larger movement equipment such as gas supports. The single printhead assembly also uses one utility bundle to supply the printhead with all the print material needed to perform a print job. Thus, the utility bundle and supply unit must have capacity to move print material to the printhead assembly in volumes required to accomplish the print plan. In the inkjet printer 100 of FIG. 1, the two supply units and two utility bundles can each have lower capacity that the supply unit and utility bundle of FIG. 2. With a single printhead assembly, the opportunities for disruptive uncoordinated movement of two printhead assemblies are eliminated.

The inkjet printer 200 has a partition 206 in the gap between the substrates 107. The partition 206 is, in this case, a plate sized to fill the gap between the substrates 107 and disposed on the substrate support 104 at a location that will fill the gap between the substrates 107 without impeding processing. The partition 206 is an optional feature for preventing intrusion or deposition of print material into or onto the substrate support 104 in the gap between the substrates. The partition 206 can prevent buildup of print material on the substrate support 104 that might require periodic cleaning. The partition 206 can be replaced at intervals to maintain the substrate support surface. The partition 206 can be made of the same material as the substrate support surface to preserve uniform thermal conditions in the processing area 140. Alternately, the partition 206 can be made of a material that resists collecting print material on the surface thereof. In some cases, the partition 206 can be provided with an electrically chargable or biasable surface to which a voltage can be applied to repel droplets of print material.

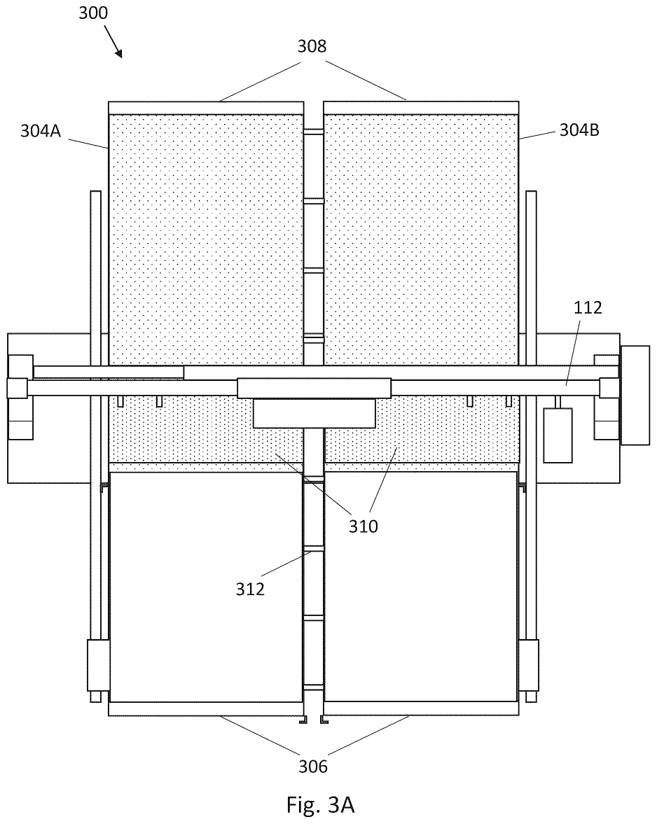

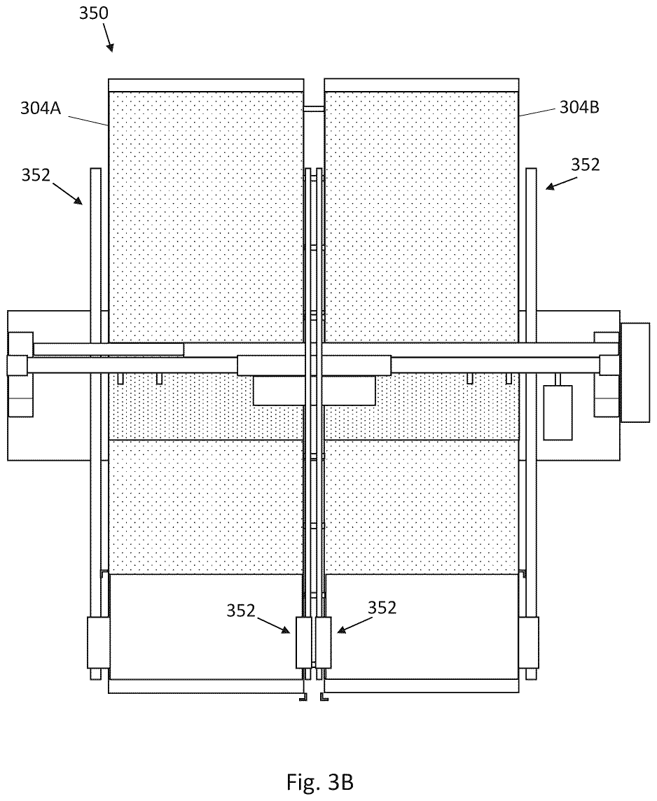

FIG. 3A is a schematic plan view of a dual-substrate inkjet printer 300 according to another embodiment. In this version, the substrate support has two unconnected substrate support surfaces 304A and 304B, so there are essentially two substrate supports across which a single print support 112 extends. Each substrate support surface 304 is sized to accommodate one substrate and to support moving one substrate from a staging area to a processing area. As in the other embodiments described herein, each substrate support surface 304 has a first staging area 306 and a second staging area 308, with a processing area 310 between the first and second staging areas 306 and 308. Each substrate support surface 304 has a longitudinal axis that extends in the direction substrates are transported from the first staging area 306 to the processing area 310, and to the second staging area 308.

The two unconnected substrate support surfaces 304A and 304B may be two totally separate substrate supports, each with its own gas flow apparatus, or the two unconnected substrate support surfaces 304A and 304B may be part of one substrate support so the two surfaces 304A and 304B share gas flow apparatus. In this case, gas flow piping 312 below the substrate support surfaces 304A and 304B is shown schematically to illustrate a single substrate support 304 with two unconnected support surfaces 304A and 304B. Such gas flow piping distributes gas to the two unconnected support surfaces 304A and 304B using a single distribution system. Flow controls (not shown) can be used to adjust flow rates to the two surfaces 304A and 304B independently.

In this case, the single printhead assembly 202 is used to print on both substrates. Alternately, the two printhead assemblies 122 could be used.

FIG. 3B is a schematic plan view of a dual-substrate inkjet printer 350 according to another embodiment. The inkjet printer 350 is equipped to process two substrates in landscape orientation. Each of the substrate support surfaces 304A and 304B has two substrate holders 352, one on each side of each substrate support surface 304A and 304B. The two opposite substrate holders 352 of one support surface can engage with opposite sides of a substrate in landscape orientation, and can be configured to move in tandem under control of a controller configured to observe a position tolerance of the two substrate holders of one support surface. For the inkjet printer 350, the substrate holders 352 are a third substrate holder and a fourth substrate holder. Movement of the substrates in landscape orientation by applying a substantially equal force to two opposite sides of the substrate substantially reduces vibrations that can arise from inertial moments of the substrates. While the inkjet printer 350 is more stable than other versions, especially when working with substrates in landscape orientation, minimum vibration and unwanted movement is still obtained when the two substrates are moved the same direction at the same time.

Each of the substrate holders 352 can be equipped with an internal pressure sensor, disposed within the gas flow pathway that couples the substrate engagement surface of each substrate holder to the vacuum or suction source, to sense a change in pressure in the gas flow pathway to indicate when the substrate engagement surface of the substrate holder 352 has successfully engaged with the substrate. A controller (not shown) can be coupled to the internal pressure sensors of the substrate holders 352 and configured to start processing of the substrate, and moving the substrate, only after both substrate holders 352 for one substrate support surface 304A or B have engaged with the substrate. In this way, premature movement of a substrate prior to engagement of both substrate holders 352, can be prevented. It should be noted that other sensors can also be used to sense engagement with the substrate. For example, a direct sensor, which can be a capacitive sensor, piezoelectric sensor, ultrasonic sensor, or optical distance or interference sensor, can be disposed in the substrate engagement surface of the substrate holders 352, to directly sense contact of the substrate with the substrate engagement surface. In such cases, the direct sensor alone can be used to detect substrate engagement, or the direct sensor can be used with a flow sensor, or other sensor, to indicate that the vacuum or suction source is operating to apply suction to the substrate engagement surface. Such sensor systems can also be used to detect and ensure full disengagement of the substrate holders 352 during substrate retrieval by a substrate handler.

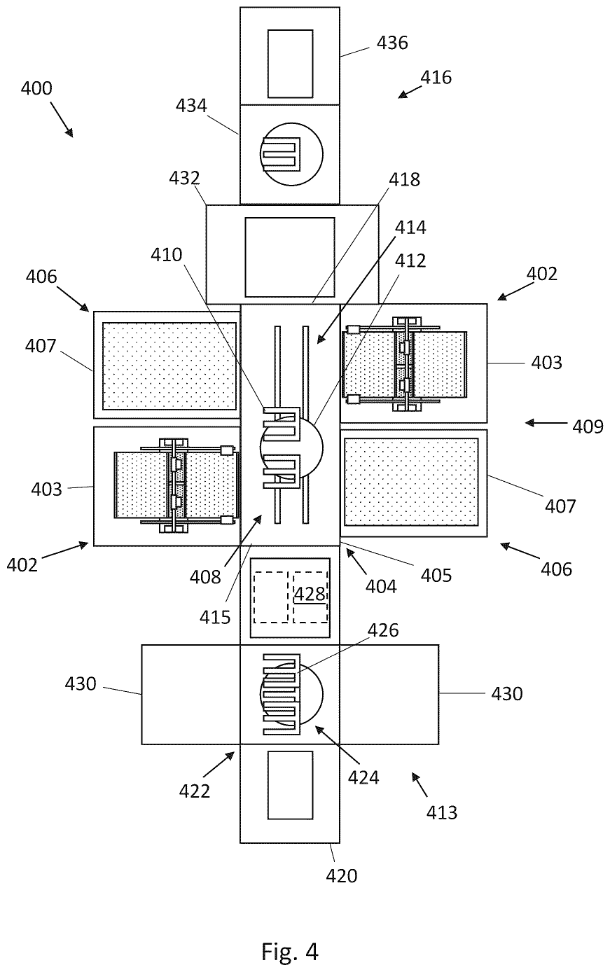

FIG. 4 is a schematic plan view of a processing system 400, according to one embodiment. The processing system 400 is an inkjet printing system that uses dual-substrate inkjet printers. This version has two dual-substrate inkjet printing chambers 402, each of which is coupled to a transfer chamber 404. Also coupled to the transfer chamber 404 are two processing chambers 406 for processing substrates after deposition of material in the dual-substrate inkjet printing chambers 402. The processing chambers 406 can each be thermal processing chambers or radiation processing chambers.

The transfer chamber 404 uses a dual-substrate robot 408 to accomplish transfer of substrates into and out of the transfer chamber 404 and between the printing chambers 402 and the processing chambers 406. The robot 408 has two blades 410 configured to move in tandem. The two blades 410 are coupled to a rotation component 412, for example a turntable, which in turn is coupled to a linear motion component 414, here represented as a track system. In a case where tracks are used, the rotation component 412 can be coupled to the tracks by one or more carriages. The robot 408 rotates to position the blades 410 to interact with the printing chambers 402, the processing chambers 406, or other chambers coupled to the transfer chamber 404, to be described further below.

In this case, the printing chambers 402 and the processing chambers 406 are coupled to the transfer chamber 404 along a long side of the transfer chamber 404, each printing chamber 402 is positioned opposite a processing chamber 406, and the two printing chamber 402 are on opposite sides of the transfer chamber 404. This configuration speeds overall processing by allowing the robot 408 to transfer substrates from, for example, a printing chamber 402 to the processing chamber 406 directly opposite without having to move linearly. The robot 408 merely retracts the blades 410 from the printing chamber 402, rotates 180 degrees, and extends the blades 410 into the processing chamber 406 immediately opposite to accomplish the substrate transfer. Avoiding linear movement during such a transfer also reduces the opportunity for vibration arising from unbalanced linear movements of the substrates. The printing chambers 402, in this case, are, include, or house portrait-mode printers like the printers 100, 200, and 300.

Each printing chamber 402 has an enclosure 403 that encloses the printer to provide a controlled processing environment in which the printer operates. Each processing chamber 406 also has an enclosure 407 in which the processing apparatus, for example radiation or thermal processing apparatus, operates. The transfer chamber 404 also has an enclosure 405 in which the robot 408 operates. The enclosures 403, 405, and 407 are in direct contact, and access between the printing chambers 402, transfer chamber 404, and processing chambers 406 are provided by doors, gates, windows, or other movable or removable barriers (not shown) that provide openings through the enclosures of the various chambers to move substrates between the chambers 402, 404, and 406.

The printing chambers 402, transfer chamber 404, and processing chambers 406 form a processing section 409 of the processing system 400. An input section 413 is coupled to a first end 415 of the transfer chamber 404. An output section 416 is coupled to a second end 418 of the transfer chamber 404 opposite from the first end 415. The transfer chamber 404 is represented here as a rectangular shape, but any convenient form can be used.

The input section 413 comprises an input load-lock chamber 420 configured to accept one substrate. A substrate loader chamber 422 is coupled to the input load-lock chamber 420, and has a substrate loader 424 configured with two blades 426 to handle one or two substrates. A dual-substrate interface chamber 428 is coupled between the substrate loader chamber 422 and the transfer chamber 404. The dual-substrate interface chamber 428 has two substrate locations to provide two substrates for handling by the robot 408 of the transfer chamber 404. The dual-substrate interface chamber 428 can have one substrate support that can accommodate two substrates, or the dual-substrate interface chamber 428 can have two substrate supports. One or more dual-substrate buffer chambers 430 may be coupled to the substrate loader chamber 422 to provide idle time if necessary for overall throughput optimization. Here, the interface chamber 428 is disposed opposite the input load-lock chamber 420 for a linear overall configuration, but other configurations can be used. With the exception of the input load-lock chamber 420, all the chambers of the input section 413 are dual-substrate chambers. The input load-lock chamber 420 may be configured to rotate a substrate from landscape to portrait orientation, for example by rotating the substrate support of the input load-lock chamber 420, in the event that substrates are delivered to the processing system 400 in landscape orientation.

A substrate is placed in the input load-lock chamber 420, using any convenient means, for processing in the system 400. If necessary, the substrate is rotated to portrait orientation by the input load-lock chamber 420 for processing. The input load-lock chamber 420 is configured with a size to allow the two blades 426 of the substrate loader 424 to advance into the input load-lock chamber 420. The two blades 426 are advanced into the input load-lock chamber 420 to retrieve the single substrate, and then retracted to bring the substrate into the substrate loader chamber 422.

The substrate can then be deposited into a buffer chamber 430, if such chamber is used, or directly into the interface chamber 428. The interface chamber 428 can be configured for independent placement and retrieval of one substrate at a time, or only for tandem placement and retrieval. Where only tandem placement and retrieval is used, a buffer chamber 430 is provided to pair substrates for transfer to the interface chamber 428. The interface chamber 428 stages substrates to be retrieved by the robot 408 of the transfer chamber 404.

The substrate loader 424 is rotated to present the substrate to the interface chamber 428 or to a buffer chamber 430, and the blades 426 are advanced into the selected chamber. At least one of the interface chamber 428 and a buffer chamber 430 is configured to accept and stage two substrates side-by-side independently. Each of the interface chamber 428 and the buffer chamber 430, or two buffer chambers 430, have substrate supports configured with substrate lifters to provide hand-off access between the substrate support and the substrate loader 424. Where the substrate supports are configured for independent placement and retrieval of two substrates positioned side-by-side, the substrate lifters are configured with linear throw to provide access for the two blades 426 of the substrate loader 424 to enter the chamber without disturbing a substrate resting on one of the substrate supports in the chamber. In other words, where one substrate lifter in a chamber is deployed for substrate placement or retrieval, the substrate lifter has an extension length that allows the two blades 426 to enter the chamber, and to move vertically to place or retrieve a substrate without disturbing another substrate in the chamber.

The buffer chambers 430 can be configured to prepare two substrates for processing, for example by bringing the two substrates to a target temperature. Each buffer chamber, so configured, may have one or more substrate sensors deployed with each substrate support to detect the presence of a substrate on the substrate support. Such sensors can be used to delay energizing any thermal control features until two substrates are loaded into the chamber to ensure uniform thermal history of the two substrates. These sensors can be ultrasonic, optical, or capacitve sensors, or where the substrates come into direct contact with a solid substrate support surface, piezoelectric sensors.

When two substrates are staged in the interface chamber 428, the robot 408 can retrieve both substrates and begin processing the substrates. After processing, the robot 408 can retrieve two substrates from any of the printing chambers 402 or the processing chambers 406 and rotate to place the substrates in the output section 416 of the processing system 400.

The output section 416 comprises a singulation chamber 432 coupled to the transfer chamber 404, a substrate unloader chamber 434 coupled to the singluation chamber 432, and an output load-lock chamber 436 coupled to the substrate unloader chamber 434. Note that the singulation chamber 432 is used where substrates must be output from the processing system 400 one at a time. If substrates are to be output from the processing system 400 in tandem, the singulation chamber 432 can be a dual-substrate load-lock chamber and the substrate unloader chamber 434 and output load-lock chamber 436 can be omitted.

It should be noted that any of the buffer chambers 430, the input load-lock chamber 420, and the output load-lock chamber 436 can have indexing capability. For example, any or all of those chambers can use a substrate support with multiple substrate locations that are horizontally or vertically distributed. A vertical indexer has multiple slots or bays arranged in a vertical frame that can be vertically actuated to provide access for an end-effector to place and retrieve substrates in a selected bay. Each bay can have a substrate support with a rack structure that can interleave with the structure of the end-effector for substrate touch-down and lift-off both of the substrate support and the end-effector. A horizontal indexer can be a carousel-type indexer that rotates to provide access for an end-effector.

The arrangement of chambers shown in FIG. 4 is an example of how such chambers could be arranged in a processing system. The same general layout of the processing system 400 could be achieved with somewhat different configuration. For example, the interfaces between some chambers can be angled to meet footprint constraints. Where, for example, the printing chambers 402 need to be angled with respect to the transfer chamber 404 to meet spacing requirements, the robot 408 can be configured to interact with the printing chamber 402 at an angle. The same is true for the processing chambers 406. In some cases, the transfer chamber 404 may have a polygonal shape that is not rectangular to accommodate angled interfaces with processing chambers. For example, where n interfaces are needed for a processing system (here, for example, 6 interfaces are needed), the transfer chamber can be configured as an n-sided polygon. In such cases, the robot of the transfer chamber can be configured to reach the chambers interfaced to the transfer chamber by simple mechanical extension, or the robot can be coupled to a circular track to travel around the transfer chamber in a circular motion. In such cases, the rotational component of the robot may be coupled to the circular track, or it may be possible to omit the rotational component.

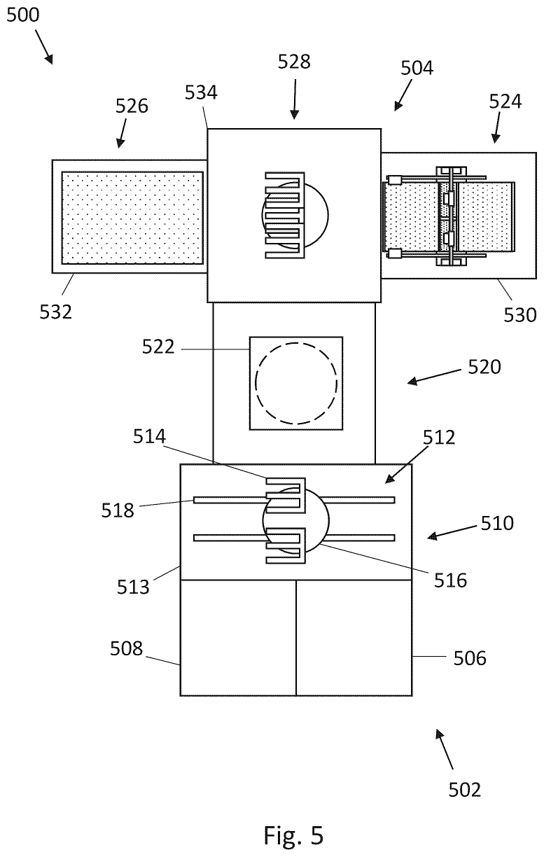

FIG. 5 is a plan view of a processing system 500, according to another embodiment. The processing system 500 differs from the process system 400 in the number of chambers used and in the input-output format used. The processing system 500 has an input-output section 502 coupled to a processing section 504. The input/out section 502 comprises an input load-lock chamber 506 and an output load-lock chamber 508 coupled to a substrate I/O chamber 510. The processing system 500 is configured for dual-substrate processing, so the input load-lock chamber 506, the output load-lock chamber 508, and the substrate I/O chamber 510 are all dual-substrate chambers for handling two substrates side-by-side. The substrate I/O chamber 510 has a dual-substrate robot 512 with two blades 514 coupled to a rotation component 516, which in turn is coupled to linear motion component 518, in this case a track system. The robot 512 is housed in an enclosure 513, in this case, which is in direct contact with the input and output load-lock chambers 506 and 508.

The input-output section 502 also has a dual-substrate interface chamber 520 configured with a rotating dual-substrate support 522. The dual-substrate support 522 can have a single substrate support surface sized to receive and hold two substrates side-by-side, or the dual-substrate support 522 can have two separate substrate support surfaces. The dual-substrate support 522 is configured to rotate so two substrates disposed on the support 522 can be presented to the processing section 504 in a desired orientation. For example, if the processing section 504 processes substrates in portrait orientation, and the substrates are delivered to the input-output section 502 in landscape orientation, the interface chamber 520 can rotate the substrates to portrait orientation for processing, and then rotate the substrates back to landscape orientation for output.

The processing section 504 here uses one printing chamber 524 and one processing chamber 526 for processing substrates after and/or before printing. The printing chamber 524 and the processing chamber 526 are coupled to a transfer chamber 528, which is also coupled to the interface chamber 520 to couple the input-output section 502 and the processing section 504 together. Each of the printing chamber 524 and the processing chamber 526 is configured for dual-substrate processing, so the printing chamber 524 has any of the printers 100-350 disposed within an enclosure 530 that provides a controlled processing environment for the printer. Because the input-output section 502 is flexible as to substrate orientation, the printing chamber 524 can be configured to process substrates in portrait or landscape orientation. The processing chamber 526 may be configured to process substrates in the same orientation as the printing chamber 524, or if helpful, the processing chamber 526 can be configured to process substrates in an orientation different from that of the printing chamber 524, and the substrate interface chamber 520 can be used to change the orientation of the substrates.

The processing chamber 526 has an enclosure 532, and the transfer chamber 528 has an enclosure 534 so that an environment internal to each of the enclosures 530, 532, and 534 can be controlled, and can be the same or different. The enclosures 530 and 532 are in direct contact with the enclosure 534, and a door, window, or other suitable barrier that can be opened and closed, provides access between the enclosures 532 and 534 and between the enclosures 530 and 534. Here, the processing chamber 526 and the printing chamber 524 are positioned on opposite sides of the transfer chamber 528, but in other embodiments, the printing chamber 524 and the processing chamber 526 could be positioned on adjacent sides of the transfer chamber 528. It should be noted that a transfer chamber having a larger number of interfaces could also be used to provide more processing and/or handling capability.

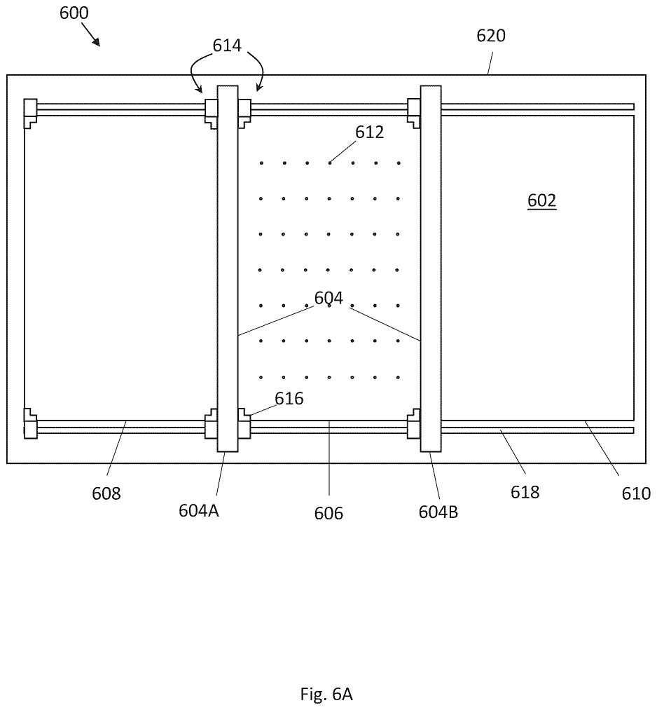

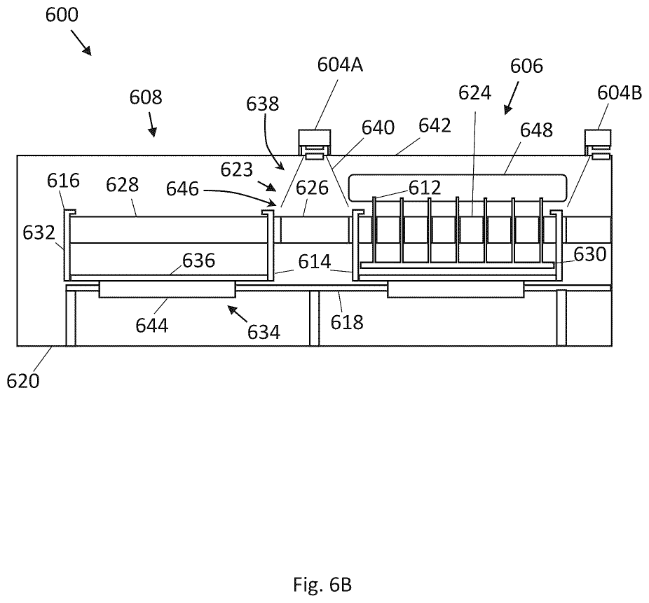

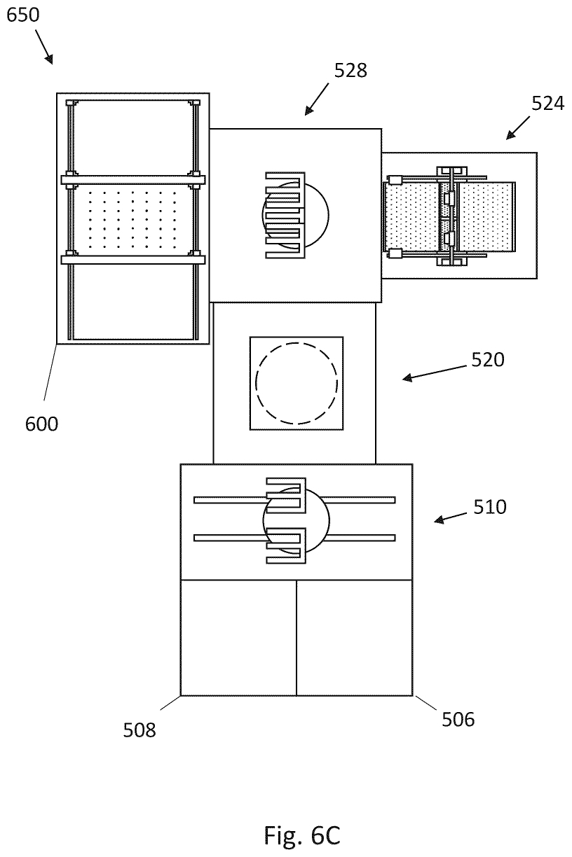

As noted above, processing chambers such as the chambers 406 and 526 can be configured for dual-substrate processing. FIG. 6A is a plan view of a radiation processing apparatus 600 according to one embodiment. The apparatus 600 is configured for radiation processing of two substrates simultaneously, concurrently, partially concurrent, partially sequentially, or sequentially, with a centrally-located in-out section and two processing sections on either side of the in-out section. The apparatus 600 has substrate support assembly 602 and one or more radiation sources 604. The substrate support assembly 602 is generally rectangular in shape with a long axis and a short axis perpendicular to the long axis. In this case there are two radiation sources 604, a first radiation source 604A associated with the first processing section 608 and a second radiation source 604B associated with the second processing section 610, each radiation source 604 an elongated member extending across the substrate support assembly 602 in the short axis direction. Each radiation source 604 has one or more radiation emitters that generally emit radiation in a direction toward the substrate support assembly 602 to irradiate an area extending across the substrate support assembly 602 in the short axis direct. The radiation sources 604 may have a single distributed radiation emitter, such as a long filament, for example in a bulb or lamp, or a plurality of emitters such as lamps or LEDs. In one case, both radiation sources 604 emit ultraviolet radiation. The two radiation sources 604 may emit radiation having the same general spectrum or wavelength, or the two radiation sources 604 may emit radiation having different spectra or wavelengths.

The substrate support assembly 602 has three sections, an in-out section 606, a first processing section 608, and a second processing section 610. The three sections are arranged side-by-side along the long axis direction of the substrate support assembly 602 with the in-out section 606 between the first process section 608 and the second processing section 610. The in-out section 606 can have a plurality of lifters 612 disposed to project through a surface of the in-out section 606 to provide lifting of substrates for substrate input and output at the in-out section 606. The three sections can use any convenient form of substrate support, such as vacuum chucking, clamping, or gas cushion support, to name a few. In this embodiment, the in-out section 606, the first processing section 608, and the second processing section 610 all use gas cushion support. Openings for gas flow through the surface of the substrate support assembly 602 are generally omitted herein to simplify the figures.

The apparatus 600 has two substrate holders 614. Each substrate holder 614 has four corner grips 616, and each holder 614 is movable in the long axis direction of the substrate support assembly 602. The corner grips 616 of each substrate holder 614 are actuated to grip and release a substrate at the corners of the substrate. In this case, the two substrate holders 614 are supported on a pair of rails 618 on opposite sides of the substrate support assembly 602 extending in the long axis direction of the substrate support assembly 602. Each holder 614 has a grip support (not shown, but located below each corner grip 616) to support the corner grips 616 and actuators (not shown, but also located under the substrate support surface) for the corner grips 616. The grip support is a structure, such as a plate or frame, movably coupled to the rails 618 by a motion system to move the substrate holder 614 along the rails 618.

The radiation sources 604 are stationary, in this case, to enable uniform processing of substrates. The radiation sources 604 are configured to allow every location on the surface of a substrate to be irradiated the same amount. Thus, the apparatus 600 is configured to scan a substrate past a radiation source 604 at a constant speed from a position entirely to one side of the radiation source 604 to a position entirely to the opposite side of the radiation source 604. The first and second processing sections 608, 610, and the in-out section 606 are all sized to accommodate a substrate with space between the sections 606, 608, and 610 to accommodate the radiation sources 604 with enough space for acceleration of substrates prior to exposure to radiation from the radiation sources 604.

Each radiation source 604 can be any convenient type of radiation source, but the two radiation sources 604 will generally be the same to afford uniform processing of substrates. In one case, the radiation sources 604 are UV LED radiation sources in a bar format. The size and output of the radiation sources 604 depends on the size of the substrates being processed. For ½ Gen 8.6 sized substrates (1,300 mm×2,250 mm), each radiation source 604 can be a 10kW UV lamp or 15 kW UV lamp with luminous output of about 5-20 W/cm2. Selection of radiation sources can be based on power availability and footprint availability.

FIG. 6B is an elevation view of a portion of the apparatus 600 showing just the in-out section 606 and the first processing section 608. The second processing section 610 is substantially identical to the first processing section 608 shown in FIG. 1B. An enclosure 620 surrounds the substrate support assembly 602, lifters 612, substrate holders 614 and rails 618. The radiation source 604A is shown here located outside the enclosure 620. The enclosure 620 has a window 622 for transmitting radiation into the enclosure 620 to irradiate a treatment zone 623 located between the in-out section 606 and the first processing section 608. The substrate support assembly 602 here has at least three parts, all of them using a gas cushion to support the substrates. An in-out part 624 corresponds to the in-out zone 606, an exposure part 626 corresponds to the treatment zone 623, and a processing part 628 corresponds to the first processing section 608. A gas source (not shown) is coupled to each part to provide gas to the area above the surface of each part, effectively forming a continuous gas cushion over the entire surface of the substrate support assembly 602.

The lifters 612 project through the in-out part 624 to engage with a substrate above the in-out part 624. The lifters 612 project from a base 630, which is coupled to a linear actuator (not shown) to extend and retract the lifters 612. The corner grips 616 are supported on posts 632 that extend from a base assembly 634. The base assembly 634 includes a linear actuator 636, in this case, that extends and retracts to move the corner grips 616 closer or farther from each other, enabling the corner grips 616 to engage with a substrate. The base assembly 634 is coupled to the rail 618. In this case, there is one rail 618, and the linear actuator 636 moves the corner grips 616 in pairs, one pair of corner grips 616 to the left of the linear actuator 636, in this view, and another pair on the right (only the corner grips in front are visible). A motion system 644 couples the base assembly 634 to the rail 618, enabling motion of the substrate holder 614.

A radiation baffle 638 is disposed within the enclosure 620 to contain radiation within the treatment zone 623 to avoid unwanted exposure of substrates outside the treatment zone 623. The radiation baffle 638 comprises two members 640 attached to an interior wall 642 of the enclosure 620 adjacent to the window 622. The two members 640 extend along the interior wall 642 of the enclosure in the short axis direction of the substrate support assembly 602 substantially the entire width thereof. The two members 640 are oriented in a divergent direction, away from each other, as they extend from the interior wall 642 toward the substrate support assembly 602 at the exposure part 626. The two members 640 extend to a location adjacent to the surface of the substrate support assembly 602 to form a gap 646 through which substrates can pass between the in-out section 606 and the first processing section 608. The substrate holder 614, holding the substrate using the corner grips 616, is actuated by the motion system 644 to move the substrate through the gap 646 for processing.

In operation, a substrate is provided to the in-out section 606 by a substrate handler. The lifters 612 are extended above the surface of the in-out section 606 to receive the substrate. The enclosure 620 has a door 648 that can be opened to allow access to the interior of the enclosure 620 by the substrate handler, and then closed after the substrate handler exits. The lifters 612 can be any type of lifter 612 convenient for scratch-free substrate processing. For example plastic or ceramic lifters with rubber tips can be used. If gas cushion support is used, the gas cushion is typically activated before, or immediately after, the substrate is received by the lifters 612.

The lifters 612 lower the substrate to a processing position, which may be a float height above the surface of the substrate support assembly 602. Referring again to FIG. 6A, where the substrate is supported by a solid object, such as a platform, the platform is movable between the in-out station 606 and one of the processing stations 608, 610. Where a platform is used, there are two platforms, as there are two sets of the substrate holders 614 in the apparatus 600. In this case, when the substrate reaches the processing position, the corner grips 616 of a substrate holder 614 are engaged with the corners of the substrate, for example by operating the linear actuator 636 of FIG. 6B to move the corner grips 616 closer together. It should be noted that instead of the corner grips 616, suction cups can be used to engage with the substrate in any convenient configuration. For example, four suction cups could be engaged at the four corners of the substrate, or two suction cups could be engaged along opposite edges of the substrate near the center of each edge. A substrate gripper that has a substrate contact surface coupled to a vacuum source, and that is coupled to a motion system, and other configurations can also be used. Where vacuum is used to engage with the substrate, the linear actuator 636 can be omitted, and a vacuum source coupled to the vacuum contacts (suction cups or grippers) to engage the substrate. The vacuum contacts would be coupled to the rail 618 and the motion system 644 of FIG. 6B.

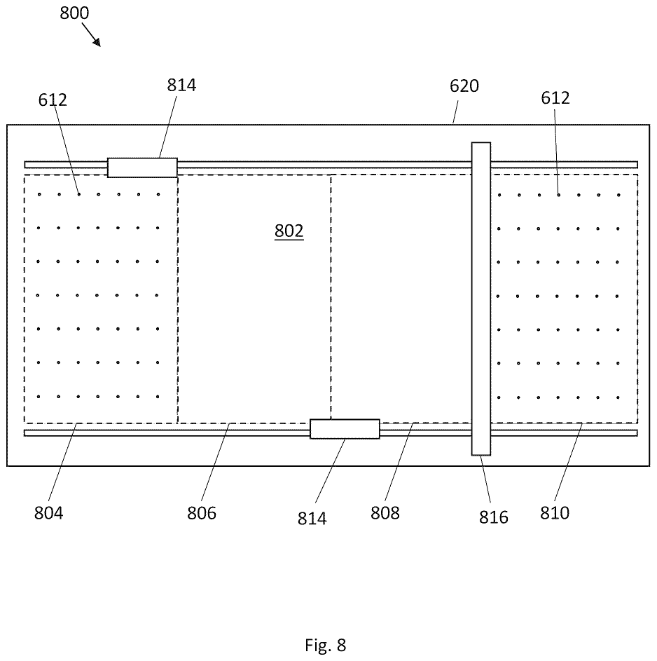

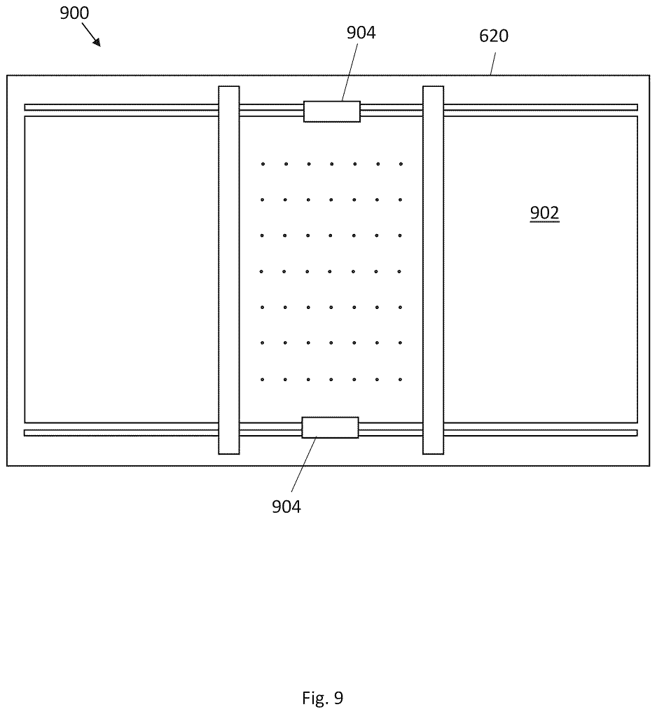

It should also be noted that where vacuum is used to engage with a substrate, a substrate holder can be used on only one side of the substrate. Thus, a substrate holder can be provided on each opposite side of the substrate support assembly to engage with a substrate, and each substrate holder can move along a linear support in the long axis direction of the substrate support assembly independent of the other substrate holder. Such substrate holders are further illustrated in FIGS. 8 and 9.

After the substrate holder 614 engages the substrate, the substrate holder 614 shifts the substrate laterally to the first processing section 608. The substrate shifts through the gap 646 of FIG. 6B, supported on the gas cushion in this case. Shifting the substrate at the earliest possible opportunity frees the in-out section 606 to handle another substrate, which may be entering or exiting the apparatus 600. The in-out section 606 can then be prepared to receive a second substrate by moving a second substrate holder 614 to the in-out section 606. While the first substrate is located in the first processing section 608, the second substrate can be moved into the in-out section 606 using the same procedure used to receive the first substrate. The second substrate will be shifted laterally to the second processing section 610 when the second holder 614 is engaged with the second substrate. While a second substrate is being loaded and shifted to the second processing section 610, the first substrate can be prepared for exposure. For example, the substrate can be idled, cooled, heated, blown with gas, or subjected any other preparation procedure.

Because the radiation sources 604 are stationary, the substrates are irradiated by shifting the substrates past the radiation sources 604. Here, there is one radiation source 604 for each of the processing sections 608, 610. Thus, a first radiation source 604A is used to irradiate substrates staged at the first processing section 108 and a second radiation source 604B is used to irradiate substrate staged at the second processing section 610. The in-out section 606 is located between the first radiation source 604A and the second radiation source 604B.

The first substrate, staged at the first processing section 608, is irradiated by shifting the first substrate from the first processing section 608 to the in-out section 606 while the first radiation source 604A is activated. Thus, when the in-out section 606 is clear, the first radiation source 604A can be activated prior to shifting the first substrate. Referring to FIG. 6B, when the first radiation source 604A is activated, radiation from the radiation source 604A is transmitted through the window 622 into the enclosure 620 between the two members 640 of the radiation baffle 638, filling the treatment zone 623 with radiation. The first substrate is shifted from the first processing section 608 to the in-out section 606 at a rate selected to provide a uniform dose of radiation to all parts of the substrate.

As noted above, the first processing section 608 and the in-out section 606 are spaced apart to allow the substrate holder 614 holding the first substrate to accelerate to a shift speed before the substrate reaches the radiation field, between the members 640, of the first radiation source 604A and to decelerate to a stop starting after the substrate leaves the radiation field of the first radiation source 604A, thus ensuring that the first substrate is shifted at a constant speed during the entire duration of exposure to the radiation of the first radiation source 604A in the treatment zone 623. After the first substrate leaves the radiation field of the first radiation source 604A, the first radiation source 604A can be deactivated to save power and reduce heat generation within the apparatus 600.

After exposure, the first substrate is located in the in-out section 606. The first substrate can then be retrieved by a substrate handler. The lifters 612 extend to raise the first substrate to allow clearance for the substrate handler to enter the apparatus 600, then lower to deposit the first substrate on the handler. The handle then withdraws, removing the first substrate from the apparatus 600. At this time, a third substrate can be provided to the in-out section 606, as described above, and shifted laterally to the first processing section 608.

While the first substrate is being exposed to radiation and removed from the apparatus 600, and while the third substrate is being provided and shifted to the first processing section, the second substrate, staged at the second processing section 610, can be prepared for exposure. When the second substrate is prepared for exposure, and the in-out section 606 is clear, the second radiation source 604B can be activated, and then the second substrate can be shifted from the second processing section 610 to the in-out section 606, thus exposing the second substrate to radiation from the second radiation source 604B. At this time, the second substrate is located at the in-out section 606, the second radiation source 604B can be deactivated, and the second substrate can be removed from the apparatus 600. The process can be repeated as many times as convenient, alternately processing two substrates, one at a time.

In some cases, radiation treatment of substrates can unsuitably affect a temperature of the substrate. As an area of the substrate enters the radiation field of one of the radiation sources 604, that area of the substrate can be heated to an extent that the temperature of the area changes by the time that area leaves the radiation field of the radiation source 604. Such temperature excursions can be unhelpful in some applications. In such cases, to avoid excessively and/or non-uniformly heating portions of a substrate during exposure, thermal control elements can be used to control temperature of the substrate during exposure.

Where gas cushion support is used, the gas used for support at the exposure zone, in the radiation field of each radiation source 604 (i.e. in the treatment zone of each radiation source), can be cooled so that the cool gas supporting the substrate removes heat from areas of the substrate that are within the radiation field. The gas can be cooled using a heat exchanger configured to cool the gas or using thermal elements disposed within the surface of the substrate support assembly 602. As an example of the latter, conduits can be provided within the material of the substrate support assembly 602, near the surface thereof, in, and optionally near, the radiation field of each radiation source 604 to flow a cooling fluid within the surface. The cooled surface can cool the gas flowing through openings in the surface.

Where a moving platform is used to support a substrate in direct contact with the surface of the platform, cooling can be applied to the entire platform to prevent any area of the substrate from rising above a critical temperature during radiation exposure. Alternately, a cooling block can be positioned opposite each radiation source 604 in close proximity to the platform to circulate cold fluid (gas or liquid) to a surface of the platform opposite from the substrate contact surface within the radiation field of the radiation sources 604. Each cooling block would have a length similar to the length of each radiation source 604. The cooling block could have a length that is slightly less than the length of the radiation source 604 and still be able to effectively control substrate temperature. A cooling block with length significantly less than the radiation source would lose cooling effectiveness at the edges of the substrate.

Temperature sensors, for example infrared sensors, can sense temperature of the substrate and a controller can use signals from such temperature sensors to control cooling. Where there is potential for overlap between thermal emission spectrum of the substrate and spectrum emitted by the radiation source, narrow band temperature sensors can be used. Cooling control can be performed by adjusting temperature of cushion gas in a gas cushion embodiment. In a platform embodiment, where a cooling block is used, cooling control can be performed by adjusting temperature and/or flow of cooling medium.

The apparatus 600 is an example of a center-feed, side-by-side dual substrate radiation processing apparatus. The primary moving components of the apparatus 600 are the substrate holders 614, and nothing above the substrates moves. Thus, substrates are irradiated efficiently and uniformly with minimal opportunity for contamination by particles. Substrate movement operations can be optimized in the apparatus 600 to parallel the longest operation using the apparatus 600 with other operations performed on another substrate. For example, in many cases, a film is formed on a substrate and then cured, 6 gelled, or solidified by processing in the apparatus 600. To achieve uniform thickness, the material on the substrate may be flowed to form a film or to reduce thickness variation of the film. In the apparatus 600, while a first substrate is engaged in a flowing process, a second substrate can be exposed and removed, and potentially a third substrate loaded and moved to a processing section. Then, while the third substrate is being flowed, the first substrate can be exposed and removed. Utilization of facilities and production rate can thus be optimized, depending on the lengths of operations.

FIG. 6C is a plan view of a processing system 650 according to another embodiment. The processing system 650 is similar to the processing system 500 in most respects, but has the radiation processing apparatus 600 instead of the processing chamber 526. The processing system 650 has the two load-lock chambers 506 and 508, the substrate I/O chamber 510, the dual-substrate interface chamber 520, the dual-substrate printing chamber 524, and the transfer chamber 528. Instead of the processing chamber 526, the processing system 650 has the radiation processing apparatus 600 for radiation processing of two substrates, making the processing system 650 a dual-substrate inkjet system. The processing system 650 is capable of single substrate input and output and dual-substrate printing and post-print processing. While the processing system 650 has the radiation processing apparatus 600 as the substrate post-print processing unit, any of the dual-substrate radiation processing apparatus described herein below can be used with the processing system 650, instead of, or in addition to, the radiation processing apparatus 600. Likewise, any of the dual-substrate radiation processing apparatus described herein, the apparatus 600, and the apparatus 700, 800, and/or 900 can be used with the processing system 400 in place of the processing chambers 406 to provide dual-substrate post-print processing for the processing system 400.

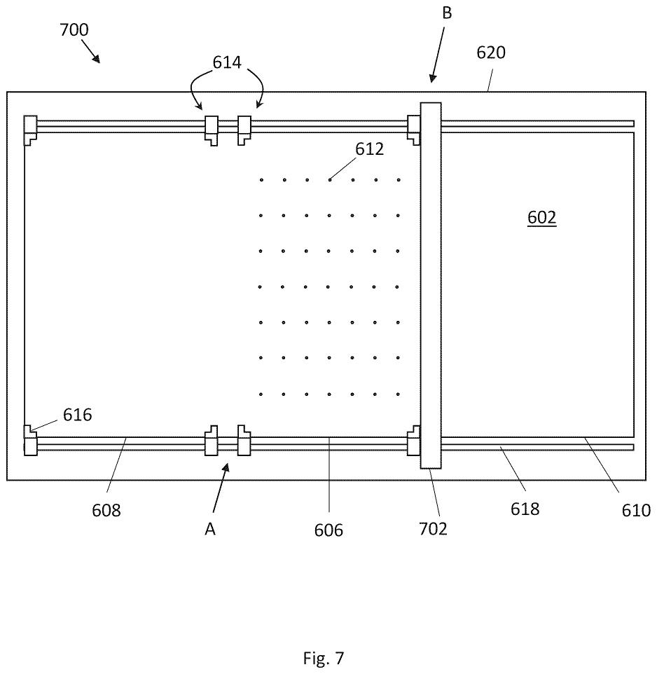

In another example, an apparatus similar to the apparatus 600 can have only one radiation source that can move between two processing sections. FIG. 7 is a plan view of a radiation processing apparatus 700 according to another embodiment. The apparatus 700 is similar in most respects to the apparatus 600, with the chief difference that the apparatus 700 has only one radiation source, a radiation source 702 that is movable to process substrates from the first and second processing sections 608 and 610 of the substrate support assembly. The radiation source 702 is an elongated component that is supported at both ends thereof by supports (not shown) located on opposite sides of the substrate support assembly 602 in the short axis direction. In this case, however, the supports are coupled to a motion system located generally below, or at an elevation lower than, the substrate support assembly 602. The motion system is not visible in FIG. 7, but is generally similar to the motion system 644 of FIG. 6B that is supported by the rail 618 (the motion system in FIG. 7 is supported by a different rail, not visible in the figure). The radiation source 702 can be located outside an enclosure, as described above in connection with FIG. 6B, with a window providing transmission of radiation to all treatment areas within the enclosure. Where the radiation source is located outside the enclosure, the motion system can be located on top of the enclosure or at a floor or support level of the enclosure.

The motion system generally comprises one or two linear supports (i.e. only one linear support, or one for each radiation source support) that extend in the long axis direction of the substrate support assembly 602 generally parallel to a plane defined by the surface of the substrate support assembly 602. Where two linear supports are used, the two linear supports will be generally parallel to the long axis of the substrate support assembly 602. A linear actuator is coupled to each linear support and to the radiation source supports. Where two linear actuators are used, the two linear actuators are operated together using a controller configured to operate the two linear actuators with very low misalignment tolerance. Operation of the one or two linear actuators moves the radiation source 702.

In one case, the radiation source 702 is moved between two processing positions, a first processing position “A” between the in-out section 606 and the first processing section 608, and a second processing position “B” between the in-out section 606 and the second processing section 610. The radiation source 702 can also be moved to a maintenance position at one end of the substrate support assembly 602.

The apparatus 700 generally operates in a manner similar to the apparatus 600 in that substrates are received at the in-out section 606 and shifted to the first and second processing sections 608 and 610 for exposure. Although the radiation source 702 is movable, the radiation source 702 is stationary during exposure of substrates to promote uniform exposure of every location of the substrate. The radiation source 702 only moves from the first processing position A to the second processing position B, and vice versa, between substrate exposures. While the radiation source 702 is located at the first processing position A, a first substrate can be exposed by shifting the first substrate from the first processing section 608 to the in-out section 606. While the radiation source 702 is located at the second processing position B, a second substrate can be exposed by shifting the second substrate from the second processing section 610 to the in-out section 606.

The apparatus 700 can be configured, as above, such that the radiation source 702 moves only between two processing positions between the sections of the substrate support assembly 602, or the apparatus 700 can be configured such that the radiation source 702 moves the entire length of the substrate support assembly 602 in the long axis direction. In some cases, the radiation source 702 can be scanned over a stationary or moving substrate to expose the substrate. In such cases, the radiation source 702 could be scanned over a substrate located in the in-out section 606, supported either by the lifters 612 or by the support mechanism (gas cushion with substrate holders or platform) at the in-out section 606.

The apparatus 600 and the apparatus 700 use a single input-output location for substrates, so the substrate input and the substrate output are in the same location or section. Such configurations can be advantageous where substrate transfer hardware and/or space available are limited. For such configurations, a single transfer device can deliver and retrieve a single substrate at a single location of the apparatus. After delivery to the apparatus 600 or the apparatus 600, a substrate moves in two opposite linear directions within the apparatus.

The apparatus 600 and 700 also use a radiation source with aperture area for emission and/or window area for transmission and/or irradiated treatment zone that is smaller than the substrate being exposed. Thus, either the substrate or the radiation source must be scanned. The apparatus 600 and 700 could be configured with radiation sources sized to expose the entire substrate without scanning. These radiation sources would be located above the processing sections 608 and 610, and would have dimensions and emissions large enough to irradiate the entire surface of substrates being treated. Substrates would be positioned in the processing sections 608 and 610, the respective radiation source would be activated for a treatment time, and then the radiation source would be deactivated. In such an apparatus, no movement would take place during exposure. These radiation sources may have dimensions substantially similar to dimensions of the substrates being treated, and may use a radiation baffle that extends directly downward from the radiation source to irradiate a treatment zone with the same area as the emission surface of the radiation source. Alternately, these radiation sources can be smaller than the substrates being irradiated, with a radiation baffle that expands outward to cover the entire surface of the substrate.

In addition to the substrate movement benefits of the apparatus 600, the apparatus 700 has the benefit of fewer radiation sources requiring less power, along with higher utilization of radiation apparatus. While the moving radiation source can risk particle generation, the risk can be minimized by moving the radiation source, between activations, only over areas of the substrate support assembly that do not have substrates loaded.

Multi-substrate radiation processing can also be performed using apparatus with different substrate input and output locations. FIG. 8 is a plan view of a radiation processing apparatus 800 according to another embodiment. The apparatus 800 has a substrate support assembly 802 with four sections, an input section 804, a preparation section 806, an exposure section 808, and an output section 810. The substrate support assembly 802 uses gas cushion support, like the other substrate support assemblies described herein. The sections are arranged sequentially in a substrate transport direction so that a substrate is transported from the input section 804 to the preparation section 806 to the exposure section 308 and then to the output section 810. Thus, in this case, substrates move through the apparatus in only one linear direction, which is oriented in the long axis direction of the substrate support assembly 802. As above, the substrate can be held by substrate holders 814, which can be as in the apparatus 600 or the apparatus 700, or in this case, side grippers. Alternately, each substrate can be supported by a platform support using, for example, a vacuum chuck.

The apparatus 800 has two substrate holders 814 located on opposite sides of the substrate support assembly 802 in the short axis direction. Each substrate holder 814 is independently positionable along the entire length of the substrate support assembly 802 so that after a substrate is engaged by lifters 612 at the output section 810, the substrate holder just released can move to the input section 804 to receive another substrate. Thus, each of the substrate holders 814 has a separate linear support and motion system. Vacuum is coupled to each of the substrate holders 814, in this case, to provide vacuum gripping of substrates. In this case, each substrate holder 814 has a vacuum surface that extends along a contact surface of the substrate holder 814, which contacts the substrate at an edge thereof. Vacuum is applied uniformly along the vacuum surface, for example through holes formed in the vacuum surface, or by using a porous material for the vacuum surface. In other embodiments, the substrate holder 814 can have suction cups to provide vacuum engagement at discrete locations.

Where platform supports are used, two platform supports can be provided on a motion system with a looped track extending over and under the substrate support assembly 802 along the long axis direction. The platforms can move, by operation of motors, along the track from the input section 804 to the output section 810 to carry substrates for processing. When a platform reaches the output section 810, lifters can engage the substrate for removal. After the substrate is removed by a substrate handler and the lifters retract, the platform just released can move along the track off the output end of the substrate support assembly 802 and under the substrate support assembly 802 to re-emerge at the input end and be positioned above the substrate support assembly 802 to receive a substrate at the input section 804.

The apparatus 800 has only one radiation source 816, which can be stationary or movable. A stationary radiation source 816, which can be similar in configuration to the radiation sources 604, is positioned between, or at the boundary between, the exposure section 808 and the output section 810. When a substrate is located at the exposure section 808 and is ready for exposure, the radiation source 816 is activated, and the substrate is shifted from the exposure section 808 to the output section 810. The radiation source 816 is then deactivated. Depending on the timing of operations, in some cases, the exposure section 808 can be omitted, and substrates can be exposed by shifting the substrate from the preparation section 806 directly to an adjacent output section 810 while being exposed to radiation from the radiation source 816 located between the adjacent preparation and output sections 806 and 810. The radiation source 816 can also be movable to scan a substrate with radiation while the substrate is either stationary or shifting. Thus, the radiation source 816 can scan a substrate while the substrate is disposed at the exposure section 808. The radiation source 816 can scan a substrate while the substrate is disposed at the preparation section 806. The radiation source 816 can also scan a substrate while the substrate is being shifted from the exposure section 808 to the output section 810, or from the preparation section 806 to the exposure section 808, or from the preparation section 806 to an adjacent output section 810, omitting the exposure section.

It should be noted that substrates can be delivered to, and retrieved from, the apparatus 800 in any convenient way. For example, substrate delivery and retrieval can be along one side of the apparatus 800, substrate delivery and retrieval can be on opposite sides of the apparatus 800, or substrate delivery and retrieval can be at opposite ends of the apparatus 800. It should also be noted that the apparatus 800 may have as many preparation stages as desired to provide time, and potentially interim processing, between input and exposure. Finally, where space is limited, the apparatus 800 could be configured such that substrates turn a corner at a convenient location of the substrate support assembly 802. Any convenient mode of substrates turning corners can be used. The substrate may rotate, or may merely change direction of linear motion without rotating. In any event, such an embodiment would feature substrates that move, within the apparatus, in two or more intersecting linear directions.

The apparatus 600, 700, and 800 are shown configured to process rectangular substrates in an orientation with the long axis of the rectangular substrate oriented along the short axis of the substrate support assemblies. If this orientation is termed “portrait” orientation, the apparatus 600, 700, and 800 can be configured to process substrates in “landscape” orientation, as well, where “landscape” is the orientation obtained by rotating a rectangular substrate that is in “portrait” orientation by 90 degrees. If necessary, substrates can be submitted to a format tool before or after processing in one of the apparatus 600, 700, or 800 to format the substrate for the apparatus.

FIG. 9 is a plan view of a radiation processing apparatus 900 according to another embodiment. In this embodiment, substrates can be handled in pairs in landscape orientation, increasing the rate that substrates are processed. The apparatus 900 has a substrate support assembly 902, also based on gas cushion support like the other versions above. Gas cushion support is used to ensure thermal uniformity of the substrates during handling, where thermal non-uniformities can result in product non-compliance. The gas for the gas cushion can be thermally controlled such that temperature variation within the material of the substrate, and any materials deposited thereon, is minimized.

Here, the substrate support assembly 902 has a short axis dimension that accommodates two substrates in landscape orientation. On each opposite side of the substrate support assembly 902 is a substrate holder 904. Each substrate holder 904 contacts one of the two substrates, such that each substrate is securely held by a substrate holder 904 while floating on the gas cushion. The substrate holders 904 may adhere to the substrates using vacuum contact or finger-style gripping, depending on the process and type of substrates. The substrate holders 904 are shown here, each with it's own linear support and independent motion system. Alternately, the substrate holders 904 can be coupled together beneath the substrate support assembly 902 and coupled to a single linear support and motion system to ensure synchronous substrate movement. In this case, the substrates can be delivered and retrieved using a substrate handler with long end effectors. When the lifters 612 engage the substrates, and the substrate holders 904 disengage, the substrate holders 904 can be moved to a location that does not interfere with access by the substrate handler. The substrate holders 904, here, are generally similar to the substrate holders 814 of FIG. 8, using a distributed vacuum surface rather than discrete vacuum locations, like suction cups.

The radiation processing apparatus described herein can be integrated into fabrication systems that deposit a material on a substrate and then irradiate the substrate to transform the deposited material. Such systems generally include a deposition apparatus to deposit a radiation susceptible material on a substrate, any of the radiation processing apparatus versions herein, and a transfer tool to move substrates between the deposition apparatus and the radiation processing apparatus.

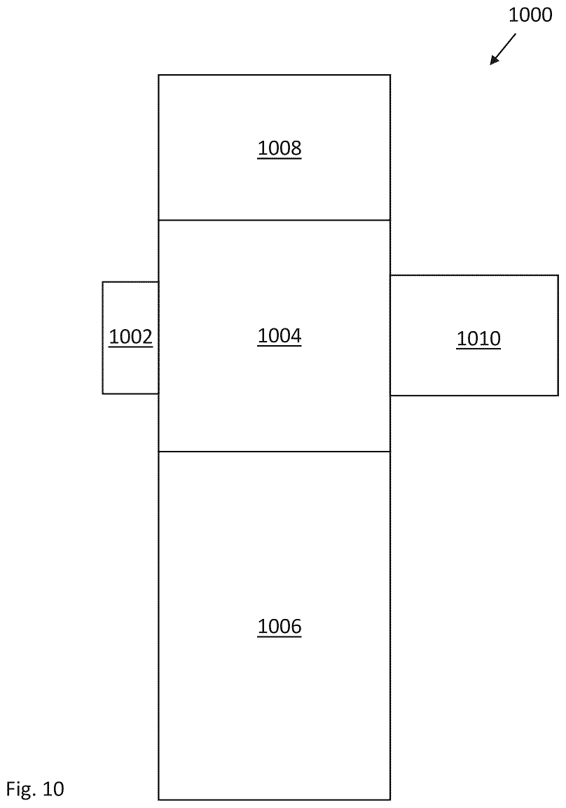

FIG. 10 is a plan view of a fabrication system 1000 according to one embodiment. The fabrication system 1000 has an input/output chamber 1002, a transfer chamber 1004, a deposition apparatus 1006, and a multi-substrate, for example dual-substrate, radiation processing apparatus 1008. The deposition apparatus 1006, which can be any kind of liquid or gas deposition apparatus, in one example an inkjet printer, is coupled to the transfer chamber 1004, along with the input/output chamber 1002 and the radiation processing apparatus 1008. The deposition apparatus 1006 can be any of the dual-substrate printing tools 100, 200, 300, or 350 described herein, or any dual-substrate printing tool to make the fabrication system 1000 a dual-substrate fabrication system. Where the fabrication system 1000 is a dual-substrate fabrication system, the input/output chamber 1002 can be a dual-substrate input/output chamber where a dual-substrate tool places two substrate into the chamber 1002, and the transfer chamber 1004 can be configured to manipulate dual substrates together in tandem.

The radiation processing apparatus 1008 can be a single input/output apparatus like the radiation processing apparatus 600 and 700 herein. The radiation processing apparatus 1008 can also be any of the processing apparatus 800 or 900. The transfer chamber 1004 has a substrate handler capable of depositing and retrieving substrates at the input/output chamber 1002, the deposition apparatus 1006, and the radiation processing apparatus 1008. It should be noted that the deposition apparatus 1006 can be a single substrate tool or a multi-substrate tool, such as a dual substrate inkjet printer. The substrate handler can be configured to handle two substrates using one end effector, for example if the radiation processing apparatus 1008 is an apparatus like the apparatus 900 (dual substrate, landscape orientation). Alternately, the substrate handler can have two end effectors, each for one substrate, that can retrieve and deliver two substrates at different times at the input/output chamber 1002, the deposition apparatus 1006, and the radiation processing apparatus 1008. A buffer chamber 1010 can also be coupled to the transfer chamber 1004. The buffer chamber 1010 can be used to idle substrates for synchronization, or can be configured as a thermal management chamber for heating or cooling substrates.

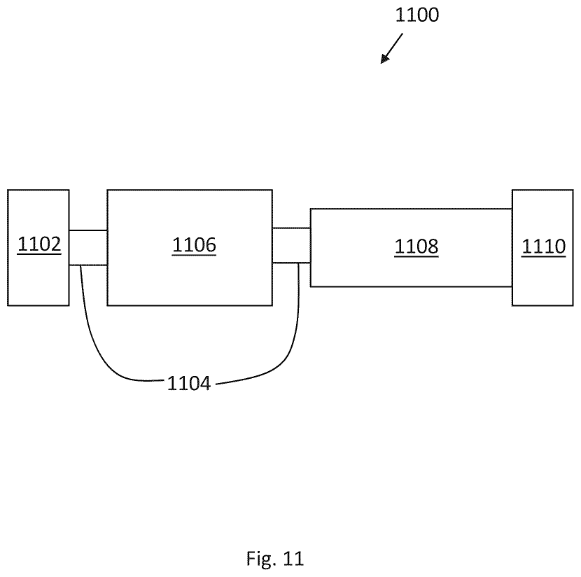

FIG. 11 is a plan view of a fabrication system 1100 according to another embodiment. The fabrication system 1100 has an input chamber 1102, a first passthrough chamber 1104, a deposition apparatus 1106, a second passthrough chamber 1104, a multi-substrate radiation processing apparatus 1108, and an output chamber 1110. The fabrication system 1100 is in a linear format, and the radiation processing apparatus is a linear end-end input/output configuration like the apparatus 800. In the system 1100, substrate are generally processed and transported in portrait configuration, but the system 1100 could be configured for landscape orientation. The deposition apparatus 1106 can be a single or dual substrate deposition apparatus, such as an inkjet printer, and can be any of the dual-substrate printers 100, 200, 300, or 350 described herein, or an embodiment of such a printer.

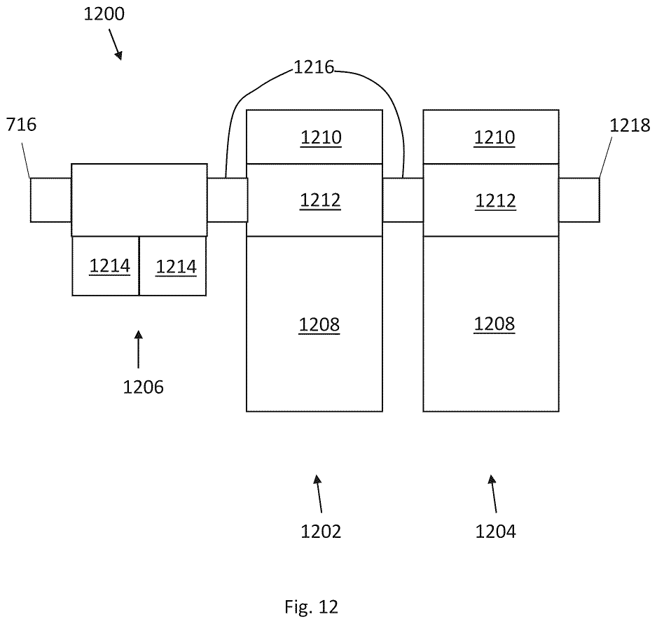

FIG. 12 is a plan view of a fabrication system 1200 according to another embodiment. The fabrication system 1200 has three main units, a first processing unit 1202, a second processing unit 1204, and an optional buffer unit 1206. Each of the first processing unit 1202 and the second processing unit 1204 has a deposition apparatus 1208 and a multi-substrate, for example dual-substrate, radiation processing apparatus 1210 coupled together by a transfer chamber 1212. The buffer unit has two buffer chambers 1214 coupled to a transfer chamber 1212. An input chamber 716 is coupled to the transfer chamber 1212 of the buffer unit 1206. The transfer chamber 1212 of the buffer unit 1206 is coupled to the transfer chamber 1212 of the first processing unit 1202 by a passthrough chamber 1216. The transfer chamber 1212 of the first processing unit 1202 is coupled to the transfer chamber 1212 of the second processing unit 1204 by a second passthrough chamber 1216. An output chamber 1218 is coupled to the transfer chamber 1212 of the second processing unit 1204. In this case, the first and second processing units 1202 and 1204 are arranged with the deposition apparatus 1208 and the radiation processing apparatus 1210 aligned on the same side, but in other cases the two processing units can be arranged in opposite orientations. In this case, each radiation processing apparatus 1210 can have a single input/output location, as in the apparatus 600 and 700, or can have an input location at one end and an output location at the opposite end, with access to the interior of the radiation processing apparatus through the side. The two radiation processing apparatus 1210 can have the same configuration, or different configuration. The deposition apparatus 1208 in each case can be a single substrate apparatus or a dual substrate apparatus. Each deposition apparatus 1208 can be an inkjet printer.

In the fabrication system 1200, the deposition units 1208 can be single substrate deposition units or dual-substrate deposition units, such as the dual-substrate tools 100, 200, 300, and 350. The transfer chambers 1212 can be configured as single substrate transfer chambers or dual-substrate transfer chambers, and the buffer units 1206 can also, likewise, be configured as single substrate or dual-substrate chambers. Thus, a single substrate robot in each transfer chamber 1212 can move single substrates into and out of the deposition units 1208, whether the deposition units 1208 are single substrate or dual-substrate units, or a dual-substrate robot in each transfer chamber 1212 can manipulate two substrates in tandem for dual-substrate deposition. Where the radiation processing apparatus 1210 are each single substrate input/output chambers, the robot of each transfer chamber 1212 can be a single substrate robot that is configured to deliver two substrates to the deposition unit 1208, where the deposition unit 1208 is a dual-substrate deposition unit.

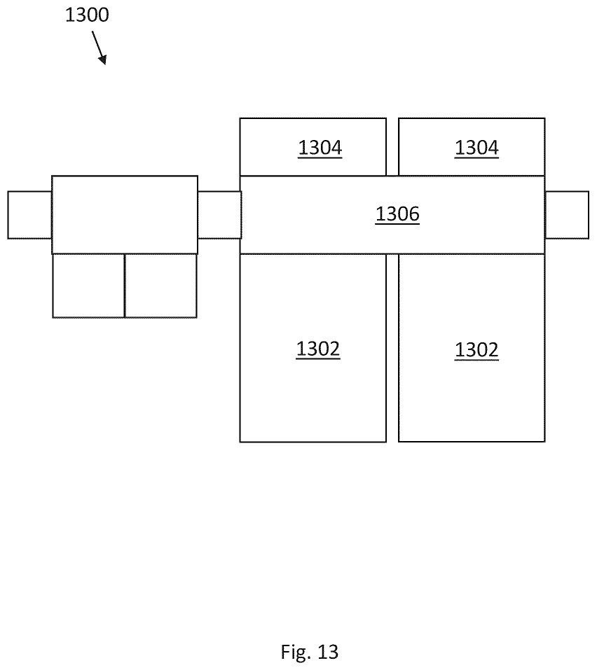

FIG. 13 is a plan view of a fabrication system 1300 according to another embodiment. The fabrication system 1300 is similar to the fabrication system 1200, except the system 1300 has two deposition apparatus 1302 and two radiation processing apparatus 1304 all coupled to a single transfer chamber 1306. As in the fabrication system 1200, the deposition apparatus 1302 can be a single substrate apparatus or a dual-substrate apparatus like any of the apparatus 100, 200, 300, or 350, and the radiation processing apparatus 1304 can each be any of the radiation processing apparatus 600, 700, 800, or 900. The transfer chamber 1306 can have a single substrate robot or a dual substrate robot, or both, as needed to manage movement of substrates through the fabrication system 1300.

While the foregoing is directed to embodiments of one or more inventions, other embodiments of such inventions not specifically described in the present disclosure may be devised without departing from the basic scope thereof, which is determined by the claims that follow.

1. An inkjet printer, comprising:
a gas cushion substrate support;
a print support extending across the substrate support and supporting a printhead assembly for dispensing material onto a substrate supported on the substrate support;
a first substrate holder on a first side of the substrate support adjacent to a first substrate location on the substrate support to move a first substrate along the substrate support; and
a second substrate holder on a second side of the substrate support opposite from the first substrate holder and adjacent to a second substrate location on the substrate support to move a second substrate along the substrate support.

2. The inkjet printer of claim 1, wherein the printhead assembly is a first printhead assembly, and further comprising a second printhead assembly supported on the print support.

3. The inkjet printer of claim 2, further comprising a controller configured to control the first and second substrate holders and the first and second printhead assemblies to position two substrates on the substrate support concurrently for processing and to move the first and second printhead assemblies along the print support and dispense print material on the two substrates.

4. The inkjet printer of claim 1, further comprising a first printhead management station at the first side of the substrate support and a second printhead management station at the second side of the substrate support.

5. The inkjet printer of claim 1, wherein the print support comprises a utility tray.

6. The inkjet printer of claim 5, wherein the printhead assembly is a first printhead assembly, and further comprising a second printhead assembly supported on the print support, a utility bundle is coupled to each of the first printhead assembly and the second printhead assembly, and each utility bundle is supported by the utility tray.

7. The inkjet printer of claim 1, wherein the substrate support has two unconnected substrate support surfaces.

8. The inkjet printer of claim 7, wherein the substrate support surfaces define a gap, and further comprising a third substrate holder and a fourth substrate holder disposed in the gap.

9. The inkjet printer of claim 8, wherein each substrate holder comprises a substrate contact detector.

10. The inkjet printer of claim 1, further comprising an imaging device movably coupled to the print support to capture images without interrupting movement of the printhead assembly.

11. An inkjet printer, comprising:
a substrate support having a gas floatation system to provide a gas cushion, the substrate support comprising a processing zone having suction openings to control a pressure of the gas cushion in the processing zone, the suction openings being arranged in two groups that define a central gap in the processing zone;
a print support extending across the substrate support at the processing zone and supporting a printhead assembly for dispensing material onto a substrate supported on the substrate support in the processing zone;
a first substrate holder on a first side of the substrate support adjacent to a first substrate location on the substrate support to move a first substrate along the substrate support; and
a second substrate holder on a second side of the substrate support opposite from the first substrate holder and adjacent to a second substrate location on the substrate support to move a second substrate along the substrate support.

12. The inkjet printer of claim 11, wherein the printhead assembly is a first printhead assembly, and further comprising a second printhead assembly supported on the print support.

13. The inkjet printer of claim 12, further comprising a controller configured to control the first and second substrate holders and the first and second printhead assemblies to position two substrates on the substrate support concurrently for processing and to move the first and second printhead assemblies along the print support and dispense print material on the two substrates.

14. The inkjet printer of claim 11, further comprising a first printhead management station at the first side of the substrate support and a second printhead management station at the second side of the substrate support.

15. The inkjet printer of claim 11, further comprising a partition disposed in the gap.

16. The inkjet printer of claim 11, wherein the substrate support has two unconnected substrate support surfaces, and further comprising a third substrate holder and a fourth substrate holder disposed between the two substrate support surfaces.

17. The inkjet printer of claim 16, wherein the gas floatation system provides the gas cushion to both support surfaces.

18. A processing system, comprising:
a processing section, comprising:
a dual-substrate inkjet printing chamber;
a dual-substrate processing chamber; and
a transfer chamber coupling the dual-substrate inkjet printing chamber and the dual-substrate processing chamber; and
a dual-substrate interface chamber coupled to the processing section to provide two substrates in side-by-side arrangement for processing in the processing section.

19. The processing system of claim 18, wherein the dual-substrate interface chamber is part of an input section that has a load-lock chamber for input of single substrates to the processing system.

20. The processing system of claim 19, wherein the load-lock chamber is an input chamber, and further comprising an output section with an output load-lock chamber for output of single substrates from the processing system, wherein the output section further comprises a singulation chamber coupled between the processing section and the output load-lock chamber, the singulation chamber having a movable substrate support to interface with a substrate unloader configured to manipulate a single substrate.

21-40. (canceled)
